(19) United States
(12) Patent Application Publication
(10) Pub. No.: US 2025/0393168 A1
(43) Pub. Date: Dec. 25, 2025

(54) HEAT DISSIPATION DEVICE AND A HEAT-CONDUCTING PLATE THEREOF

(71) Applicant: PURPLE CLOUD DEVELOPMENT PTE. LTD., Singapore (SG)

(72) Inventors: YANGZHOU CAI, Singapore (SG); WENJIAN ZHANG, Singapore (SG); CONG HE, Singapore (SG); LIUPING FENG, Singapore (SG)

(73) Assignee: PURPLE CLOUD DEVELOPMENT PTE. LTD., Singapore (SG)

(21) Appl. No.: 19/243,822

(22) Filed: Jun. 20, 2025

(30) Foreign Application Priority Data
Jun. 21, 2024 (CN) 202421437268.7
Jun. 21, 2024 (CN) 202421437286.5
Jun. 21, 2024 (CN) 202421439696.3

(51) Int. Cl. H05K 7/20

(52) U.S. Cl. CPC H05K 7/2039

(57) ABSTRACT

A heat dissipation device includes a heat-conducting plate having a plate body and a cover mounted to the plate body. The plate body and the cover together define a vapor chamber. At least one partition rib is provided in the plate body to divide the vapor chamber into at least two first partition chambers. A first end of the partition rib is connected to a sidewall of the vapor chamber, and a second end of the partition rib extends into the vapor chamber and is spaced apart from an opposite sidewall of the vapor chamber by a gap. A second partition chamber is formed between the second end of the partition rib and the opposite sidewall and is in fluid communication with the at least two first partition chambers, and the partition rib tapers from the first end towards the second end.

### CROSS-REFERENCE TO RELATED APPLICATIONS

This application is a non-provisional application and claims the benefit of priority to: Chinese Patent Application No. 202421439696.3, filed on Jun. 21, 2024; Chinese Patent Application No. 202421437286.5, filed on Jun. 21, 2024; and Chinese Patent Application No. 202421437268.7, filed on Jun. 21, 2024. The contents of each of the foregoing applications are incorporated herein by reference in their entirety.

### TECHNICAL FIELD

The present disclosure relates to the field of heat dissipation technology, and more particularly, to a heat dissipation device incorporating a heat-conducting plate.

### BACKGROUND

With the development of technology, the performance of electronic components in devices has significantly improved. However, as these components become more powerful, they also generate more heat during operation. This tendency has led to an increasing demand for better thermal management in electronic devices.

Traditionally, a common method for heat dissipation employs a heat-conducting plate. The heat-conducting plate transfers heat generated by electronic components to heat-dissipating fins, which disperse the heat.

However, these conventional heat dissipation devices typically employ a heat-conducting plate with a single vapor chamber. After absorbing heat from heat-generating components, vapor is generated and moved longitudinally and laterally within the chamber. As a result, the vapor movement becomes chaotic and disorganized, thereby decreasing heat dissipation efficiency. Therefore, the conventional heat dissipation devices often have inferior thermal performance.

### SUMMARY

In general terms, this disclosure is directed to a heat dissipation device that incorporates a heat-conducting plate. In some embodiments, and by non-limiting example, the present disclosure provides a novel design of the heat-conducting plate. The design facilitates rapidly and efficiently outward direction of vapor within the heat-conducting plate, consequently enhancing the thermal conductivity and heat dissipation efficiency of the plate, thereby improving the overall performance of the heat dissipation device.

An aspect of the present disclosure provides a heat-conducting plate. The heat-conducting plate includes a plate body, and a cover that is mounted to the plate body, wherein the plate body and the cover together define a vapor chamber, the plate body includes at least one partition rib that partitions the vapor chamber into at least two first partition chambers, a first end of the partition rib is connected to a sidewall of the vapor chamber, and a second end of the partition rib extends into the vapor chamber and is spaced apart from an opposite sidewall of the vapor chamber by a gap, a second partition chamber is formed between the second end of the partition rib and the opposite sidewall and is in fluid communication with the at least two first partition chambers, and the partition rib tapers from the first end towards the second end.

In one embodiment, the plate body includes multiple partition ribs that are arranged in parallel and spaced at equal intervals.

In one embodiment, the partition rib protrudes from a bottom surface of the vapor chamber towards the cover.

In one embodiment, a plurality of thermal conduction support pillars are disposed within the vapor chamber, a first end of the conduction support pillar is connected to the bottom surface of the vapor chamber, and a second end of the conduction support pillar contacts the cover.

In one embodiment, at least one conduction support pillar is integrally formed with a corresponding partition rib.

In one embodiment, the conduction support pillar is designed as a cylindrical post.

In one embodiment, the first end of each first partition chamber includes a fin locking groove.

In one embodiment, the cover includes at least two through-slots, and each of the first partition chambers is in fluid communication with a corresponding through-slot.

Another aspect of the present disclosure provides a heat dissipation device. The heat dissipation device includes a heat-conducting plate having a plate body; and a cover having at least two through-slots, the cover being mounted to the plate body, wherein the plate body and the cover together define a vapor chamber, the plate body includes at least one partition rib that partitions the vapor chamber into at least two first partition chambers, each of the first partition chambers being in fluid communication with a corresponding through-slot, a first end of the partition rib is connected to a sidewall of the vapor chamber, and a second end of the partition rib extends into the vapor chamber and is spaced apart from an opposite sidewall of the vapor chamber by a gap, a second partition chamber is formed between the second end of the partition rib and the opposite sidewall and is in fluid communication with the at least two first partition chambers, and the partition rib tapers from the first end towards the second end. The heat-dissipation device further includes a plurality of heat dissipation fins, each of the heat dissipation fins extending into a corresponding first partition chamber through a respective through-slot, at least one securing strip configured to secure the heat dissipation fins, and a fin protection member configured to protect the heat dissipation fins.

In one embodiment, each of the heat dissipation fins includes at least one insertion rib, each insertion rib extending into a corresponding first partition chamber through a respective through-slot.

In one embodiment, each insertion rib has at least one communication opening, and the communication opening extends into a corresponding first partition chamber when the heat dissipation fin is inserted into the heat-conducting plate.

In one embodiment, each insertion rib includes a communication section that protrudes vertically from the insertion rib, the communication opening is formed in the communication section, each through-slot is recessed outward from both lateral sides along a horizontal direction to form a clearance groove, and the clearance groove is shaped and positioned to accommodate a corresponding communication section.

In one embodiment, the securing trip includes at least two first locking slots, the heat dissipation fin includes at least two second locking slots, and the first locking slots are aligned in a one-to-one correspondence with the second locking slots.

In one embodiment, the protection member has a mesh structure and is attached to the heat dissipation fins on a side of that faces away from the heat-conducting plate.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

FIG. 1 is an exploded view of a heat-conducting plate in accordance with one embodiment of the present disclosure.

FIGS. 2-3 are schematic diagrams of the plate body shown in FIG. 1.

FIG. 4 is an enlarged view of portion A in FIG. 2.

FIG. 5 is a schematic diagram of the cover shown in FIG. 1.

FIG. 6 is an enlarged view of portion B in FIG. 5.

FIGS. 7-8 are schematic diagrams of a heat dissipation device in accordance with one embodiment of the present disclosure.

FIG. 9 is an exploded view of the heat dissipation device shown in FIG. 7 after removal of the heat-conducting plate.

FIG. 10 is an enlarged view of portion C in FIG. 9.

FIG. 11 is a schematic diagram of the heat dissipation fins shown in FIG. 7.

FIG. 12 is an enlarged view of portion D in FIG. 11.

FIG. 13 is a schematic diagram of the securing strip shown in FIG. 7.

FIG. 14 is an enlarged view of portion E in FIG. 13.

FIG. 15 is a schematic diagram of a plate body of a heat-conducting plate in accordance with another embodiment of the present disclosure.

FIG. 16 is a schematic diagram of a shovel-tooth fin unit shown in FIG. 15.

FIG. 17 is a schematic diagram of a plate body of a heat-conducting plate in accordance with another embodiment of the present disclosure.

FIG. 18 is an partially enlarged view of the plate body shown in FIG. 17.

FIG. 19 illustrates alternative views of a staggered fin unit shown in FIG. 17.

FIG. 20 illustrates alternative partial enlarged views of the staggered fin unit shown in FIG. 17.

### DETAILED DESCRIPTION

Various embodiments will be described in detail with reference to the drawings, wherein like reference numerals represent like parts and assemblies throughout the several views. Reference to various embodiments does not limit the scope of the claims attached hereto. Additionally, any examples set forth in this specification are not intended to be limiting and merely set forth some of the many possible embodiments for the appended claims.

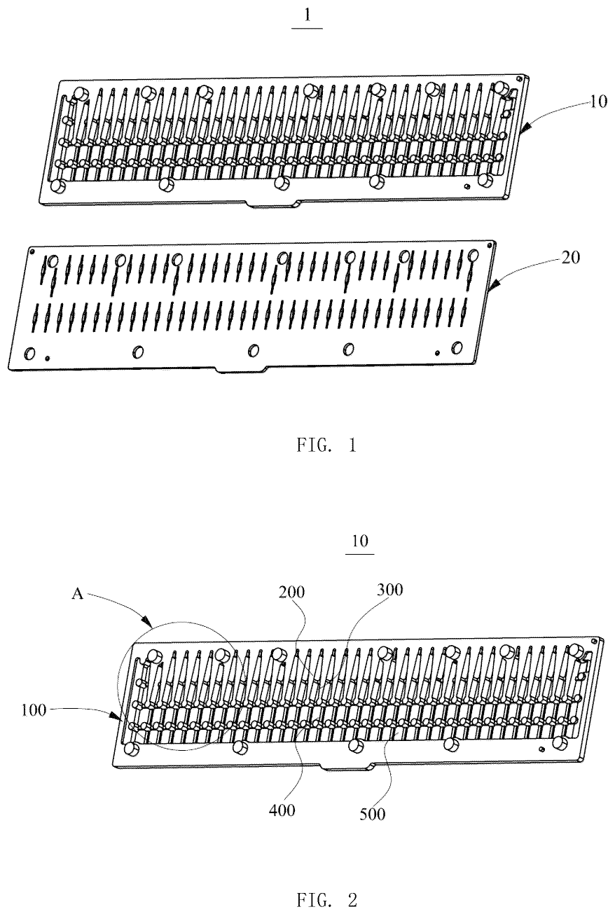

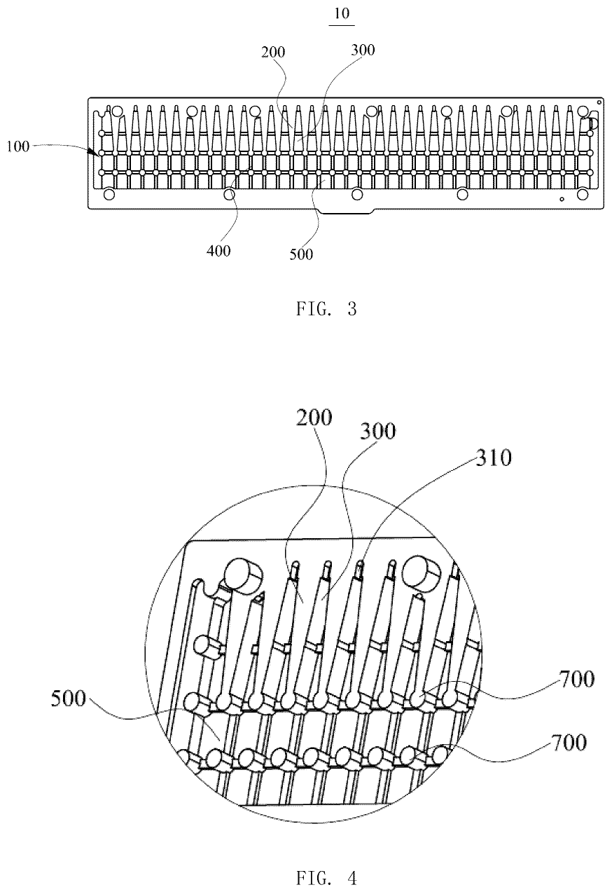

Referring to FIGS. 1-4. FIG. 1 is an exploded view of a heat-conducting plate in accordance with one embodiment of the present disclosure. FIGS. 2-3 are schematic diagrams of the plate body shown in FIG. 1. FIG. 4 is an enlarged view of portion A in FIG. 2. As an example illustrated in FIG. 1, the heat-conducting plate 1 includes a plate body 10 and a cover 20. The plate body 10 and the cover 20 are coupled together to define an enclosed vapor chamber 100.

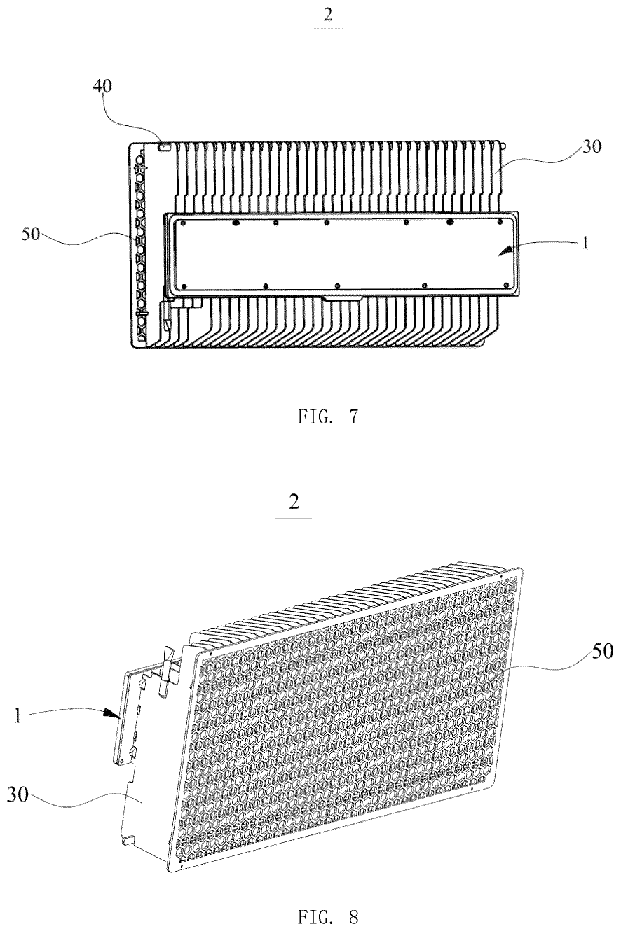

In one embodiment, the plate body 10 further includes at least one partition rib 200. The partition rib 200 protrudes from a bottom surface of the vapor chamber 100 towards the cover 20. The partition rib 200 divides the vapor chamber 100 into at least two first partition chambers 300. A first end of the partition rib 200 is connected to one sidewall of the vapor, and the second end of the partition rib 200 extends into the vapor chamber 100 and is spaced apart from the opposite sidewall by a gap 400. A second partition chamber 500 is formed between the second end of the partition rib 200 and the opposite sidewall and is in fluid communication with the at least two first partition chambers 300. As the working fluid in the second partition chamber 500 heats up and vaporizes, the resulting vapor is driven under pressure into the first partition chambers 300 and then move towards the heat dissipation fins 30 (shown in FIG. 7) for effective cooling.

In one embodiment, the partition rib 200 is tapered from the first end towards the second end, which results in the first partition chambers 300 progressively narrowing as they extend away from the second partition chamber 500. In some embodiments, the shape of the partition rib 200 may vary, provided that it leads to a narrowing configuration in the first partition chambers 300 in the specified direction.

In one embodiment, multiple partition ribs 200 are arranged in parallel and evenly spaced. The working fluid within the heat-conducting plate 1 is heated, thereby transitioning from liquid to vapor. The vapor enters the first partition chambers 300 from the second partition chambers 500. In each first partition chambers 300, the vapor flows from an end close to the second partition chamber 500 towards an opposite end. As the first partition chamber 300 tapers from the end close to the second partition chamber 500, its cross-sectional area gradually decreases along the flow direction. Assuming a constant input power, the volume of the generated vapor remains constant. Therefore, as the vapor flows through the narrowing first partition chambers 300, its velocity increases. This results in greater efficiency in vapor transport from the vapor chamber 100 to the heat dissipation fins 30, thereby accelerating the phase-change cycle. As a result, the thermal dissipation efficiency of the heat-conducting plate 1 is enhanced, hence improving the overall cooling performance of the heat dissipation device.

In one embodiment, a plurality of thermal conduction support pillars 700 are disposed within the vapor chamber 100. A first end of the conduction support pillar 700 is connected to the bottom surface of the vapor chamber 100, and a second end of the conduction support pillar contacts the cover 20. At least one conduction support pillar 700 is integrally formed with a corresponding partition rib 200.

In one embodiment, the conduction support pillars 700 are evenly distributed throughout the vapor chamber 100, with each conduction support pillar 700 designed as a cylindrical post. However, the embodiment is not limited thereto. In other embodiments, the conduction support pillars 700 can be arranged in various patterns and may adopt various shapes to meet specific specification. According to the embodiments, the conduction support pillars 700 transfer the heat from the plate body 10 to the heat dissipation fins 30 (shown in FIG. 7) via the cover 20.

Additionally, by integrating the conduction support pillars 700 with the partition ribs 200, the structure provides dual benefits: it reinforces the cover 20 against deformation and efficiently transfers heat from the plate body 10 to the heat dissipation fins 30. This integrated configuration not only strengthens the mechanical support for the cover 20 but also extends the heat conduction pathway. The unified design facilitates the transfer of heat from the plate body 10 to the heat dissipation fins 30 via the cover 20, thereby enhancing the thermal dissipation capabilities of the heat-conducting plate 1 and ultimately improving the overall cooling performance of the heat dissipation system.

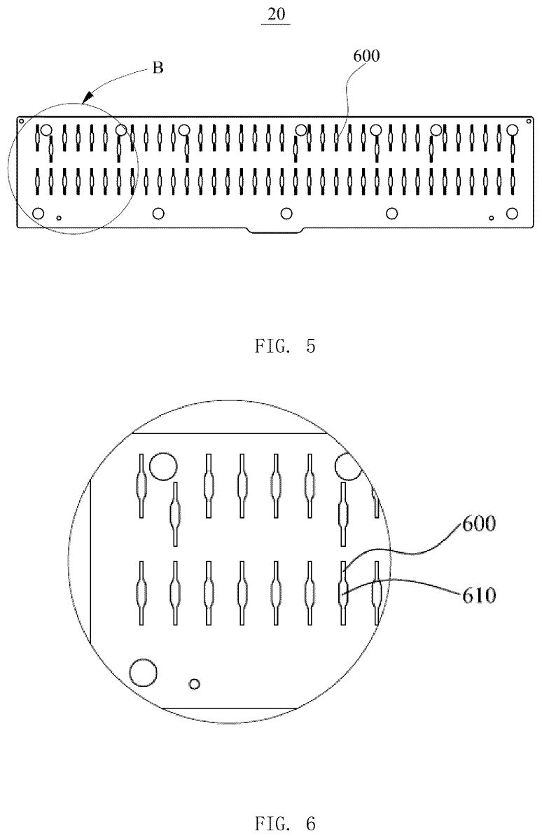

Referring to FIGS. 5-6. FIG. 5 is a schematic view of the cover shown in FIG. 1. FIG. 6 is an enlarged view of portion B in FIG. 5. As an example illustrated in FIGS. 5-6, the cover 20 includes at least two through-slots 600.

In one embodiment, the first partition chamber 300 (shown in FIG. 2) is in fluid communication with at least one of the through-slots 600. The configuration allows air, vapor, or other working media to travel between the partition chamber and the corresponding through-slot, facilitating heat regulation or pressure balancing within the system.

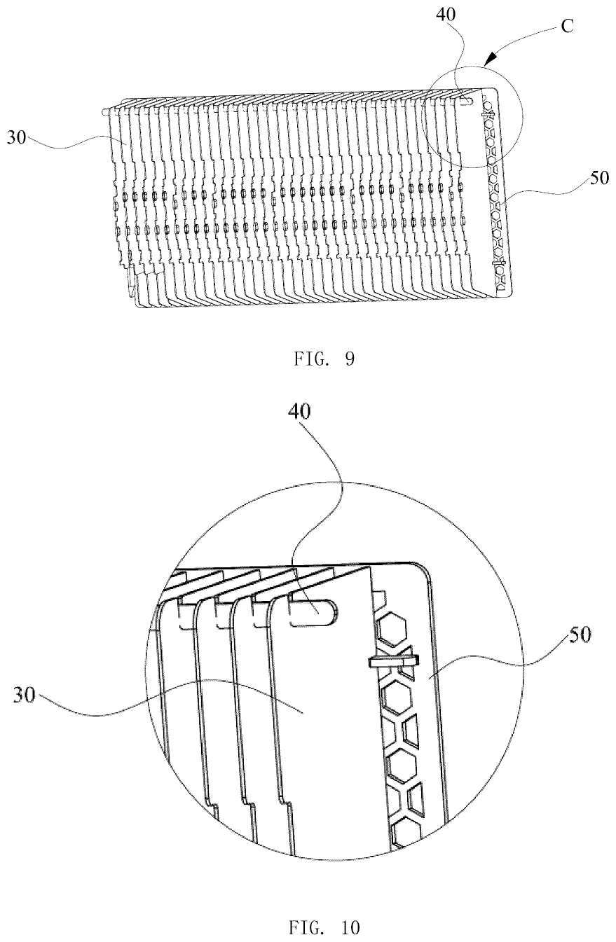

Referring to FIGS. 7-8. FIGS. 7-8 are schematic diagrams of a heat dissipation device in accordance with one embodiment of the present disclosure. As an example illustrated in FIGS. 7-8, the heat dissipation device 2 includes a heat-conduction plate 1 and at least two heat dissipation fins 30.

In one embodiment, each heat dissipation fin 30 passes through a through-slot 600

(shown in FIG. 6) and extends into a corresponding first partition chamber 300 (shown in FIG. 2). The first partition chambers 300 and the heat dissipation fins 30 are arranged in a one-to-one correspondence, ensuring efficient thermal conduction and structural alignment. However, the embodiment is not limited thereto. In other embodiments, depending on specific thermal management requirements, each first partition chamber 300 can accommodate multiple heat dissipation fins 30, facilitating adaptable responses to varying cooling demands.

In one embodiment, the heat dissipation device 2 further includes a fin protection member 50. The fin protection member 50 has a mesh structure and is attached to the side of the heat dissipation fins 30 that faces away from the heat-conducting plate 1. The fin protection member 50 protects the heat dissipation fins 30 from physical damage while maintaining their thermal performance without impeding heat dissipation.

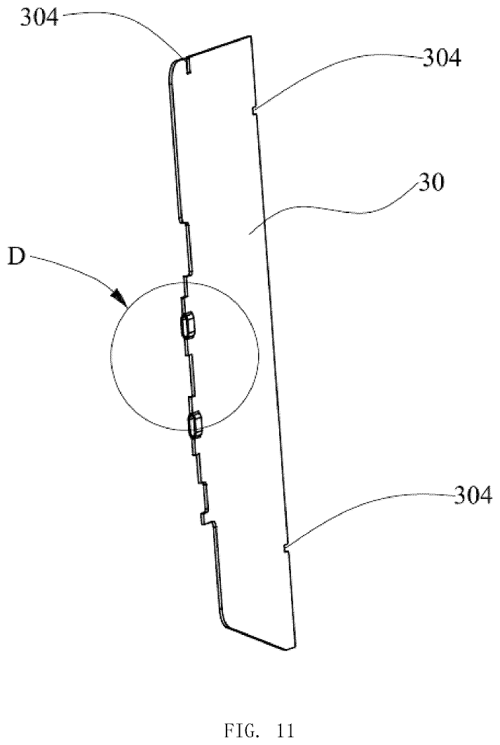

Referring to FIGS. 9-10. FIG. 9 is an exploded view of the heat dissipation device shown in FIG. 7, subsequent to the removal of the heat-conducting plate 1. FIG. 10 is an enlarged view of portion C in FIG. 9. As an example illustrated in FIGS. 9-10, the heat dissipation device 2 further includes at least one securing strip 40.

In one embodiment, the securing strip 40 is configured to secure the heat dissipation fins 30. For example, three securing strips 40 can be employed to engage at least two surfaces of the heat dissipation fins 30, enhancing the stability and reliability of the fin mounting. However, the embodiment is not limited thereto. In another embodiment, the number of securing strips 40 can be varied depending on specific requirements, providing for adaptable and tailored fin stability.

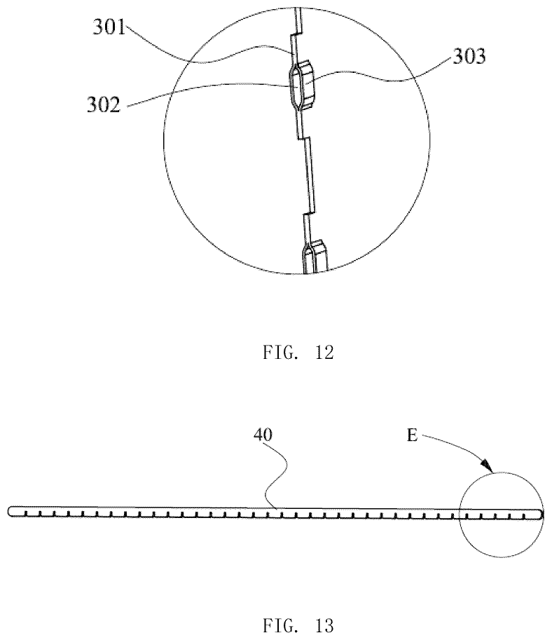

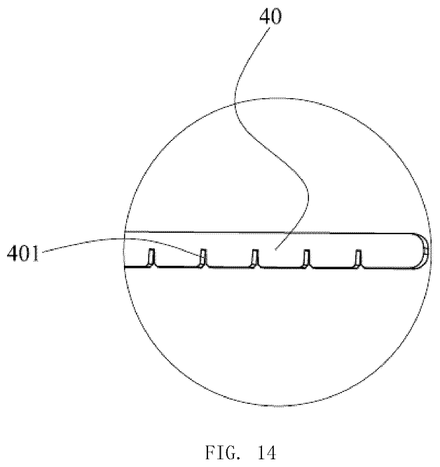

Referring to FIGS. 11-14 along with FIG. 6. FIG. 11 is a schematic diagram of the heat dissipation fins shown in FIG. 7. FIG. 12 is an enlarged view of portion D in FIG. 11. FIG. 13 is a schematic diagram of the securing strip 40 shown in FIG. 7. FIG. 14 is an enlarged view of portion E in FIG. 13. As an example illustrated in FIG. 14, the securing trip 40 includes at least two first locking slots 401. As an example illustrated in FIG. 11, the heat dissipation fin 30 includes at least two second locking slots 304 corresponding to the first locking slots 401.

In one embodiment, the first locking slots 401 are aligned in a one-to-one correspondence with the second locking slots 304. The configuration enables the securing strip 40 to securely anchor the heat dissipation fins 30, facilitating a robust and stable installation. This configuration effectively prevents any loosening, detachment, or displacement of the fins during operation, ensuring excellent performance and reliability.

In one embodiment, the heat dissipation fin 30 includes at least one insertion rib 301, which corresponds to a through-slot 600. The insertion rib 301 passes through its corresponding through-slot 600 and extends into the vapor chamber 100. Specifically, after the insertion rib 301 of the heat dissipation fin 30 passes through its corresponding through-slot 600, it extends into a corresponding first partition chamber 300. The insertion rib 301 includes at least one communication opening 302. Upon the installation of the heat dissipation fin 30 onto the heat-conducting plate 1, the communication opening 302 extends into the first partition chamber 300.

In one embodiment, the number of heat dissipation fins 30 matches the number of first partition chambers 300, with each fin 30 directly aligned with its associated first partition chamber 300 in a one-to-one correspondence. In this embodiment, each heat dissipation fin 30 is equipped with two insertion ribs 301. However, the embodiment is not limited thereto. In other embodiments, each dissipation fin 30 can be equipped with more than two insertion ribs 301, thereby enhancing structural support and alignment capabilities.

In one embodiment, each insertion rib 301 includes at least one protruding communication section 303 that projects vertically from the surface of the insertion rib 301. The communication opening 302 is formed within the communication section 303. Correspondingly, as shown in FIG. 6, each through-slot 600 is recessed outward from both lateral sides along a horizontal direction, forming a clearance groove 610. The clearance groove 610 is designed and positioned to accommodate the communication section 303. During assembly, the communication section 303 aligns with and passes through the clearance groove 610. Upon insertion, the communication section 303 and its communication opening 302 allow fluid communication between the heat dissipation fin 30 and the corresponding first partition chamber 300.

In one embodiment, after the insertion rib 301 is inserted into the first partition chamber 300, a fin-locking groove 310 (shown in FIG. 4) formed at the first end of the first partition chamber 300 engages and restricts the end of the insertion rib 301. Then, the fin-locking groove 310 secures position the insertion rib 301, firmly locking the heat dissipation fin 30 in place. As a result, the connection between the heat dissipation fin 30 and the heat-conducting plate 1 has been improved, thereby preventing the fins from loosening or detaching during operation.

According to the embodiments above, the heat dissipation device 2 improves thermal performance by incorporating a partition rib 200 into the heat-conducting plate 1. The partition rib 200 gradually tapers from an end connected to the sidewall of the vapor chamber 100 to an opposite end, leading to the first partition chamber 300 to narrow progressively from an end close to the second partition chamber 500 towards an opposite end. The tapered structure of the first partition chamber 300 compresses and accelerates the flow of vapor, hence enhancing the vapor pressure and flow velocity. As a result, the vapor within the heat-conducting plate 1 is rapidly directed via the first partition chamber 300 towards the heat dissipation fins 30. The configuration described above enhances the heat transfer efficiency of the heat-conducting plate 1, thereby improving the overall thermal performance of the heat dissipation device 2.

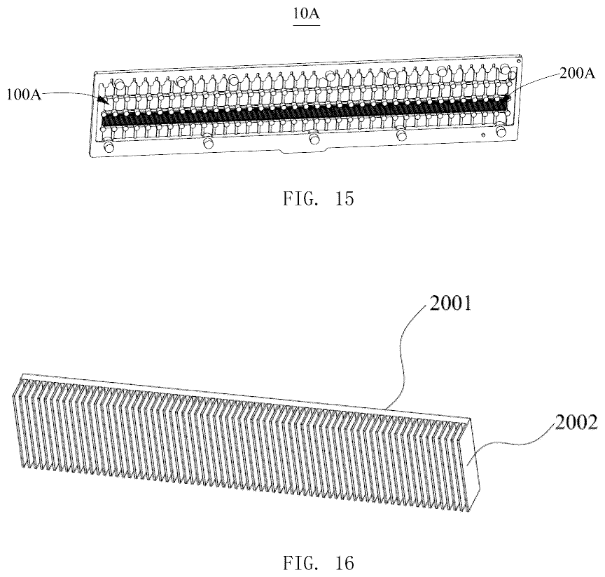

Referring to FIGS. 15-16. FIG. 15 is a schematic diagram of a plate body of a heat-conducting plate in accordance with another embodiment of the present disclosure. FIG. 16 is a schematic diagram of shovel-tooth fins units 200A shown in FIG. 15. The plate body 10A of the heat-conducting plate in this embodiment is similar to the plate body 10, so the similarities will not be repeated hereunder. In this embodiment, the plate body 10A is integrated into the heat-conducting plate. The primary distinction between the heat-conducting plate 1 and this embodiment lies in the unique structure of the plate body 10A, while the remaining structural elements are consistent. According to this embodiment, the heat dissipation device includes the heat-conducting plate, which features the plate body 10A. The key difference in this configuration, compared to the heat dissipation structure 2, is the specific design of the plate body 10A, with all other components and characteristics remaining identical.

As an example illustrated in FIGS. 15-16, the vapor chamber 100A includes a plurality of shovel-tooth fin units 200A. The shovel-tooth fin units 200A are brazed within the vapor chamber 100A and are sequentially aligned along its longitudinal axis. In one embodiment, the shovel-tooth fins unit 200A includes a base plate 2001 and at least one heat exchange fin 2002. The base plate 2001 is attached to the bottom of the vapor chamber 100A, and the heat exchange fins 2002 are positioned on the side of the base plate 2001 that faces away from the vapor chamber 100A. In one embodiment, the heat exchange fins 2002 are evenly spaced and arranged in parallel on the base plate 2001. However, the embodiment is not limited thereto. In other embodiments, the heat exchange fins 2002 can be arranged in different configurations to meet specific thermal management needs.

In one embodiment, the base plate 2001 may be made of copper, aluminum, or a copper-aluminum bimetal plate. The heat exchange fins 2002 may be copper, aluminum, or copper-aluminum bimetal fins.

During operation, the plate body 10A is in contact with the heat-generating region of an electronic device to dissipate heat. The shovel-tooth fins units 200A are deliberately positioned to align with the high-power areas of the device that produce the most heat. The plate body 10A absorbs heat from the high-power areas and swiftly transfers it to the shovel-tooth fins units 200A. Subsequently, the shovel-tooth fins units 200A transfer the absorbed heat to the working fluid within the vapor chamber 100A, enhancing the local heat exchange efficiency of the plate body 10A.

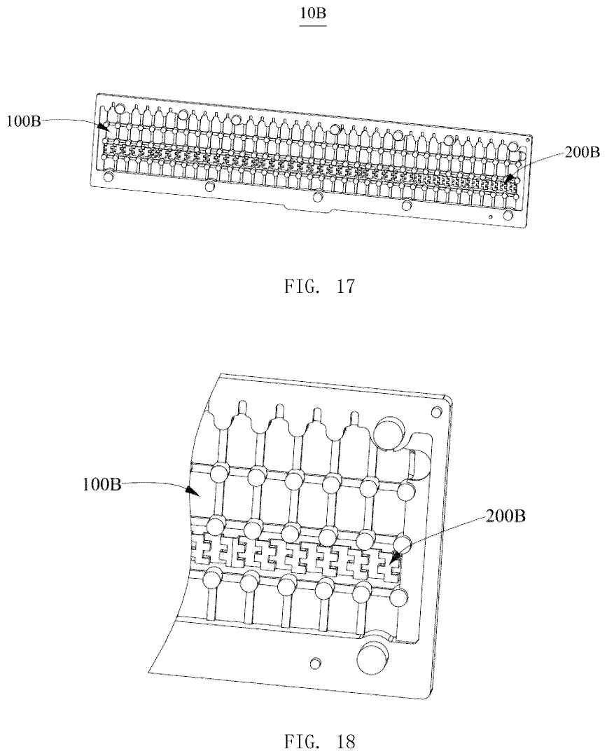

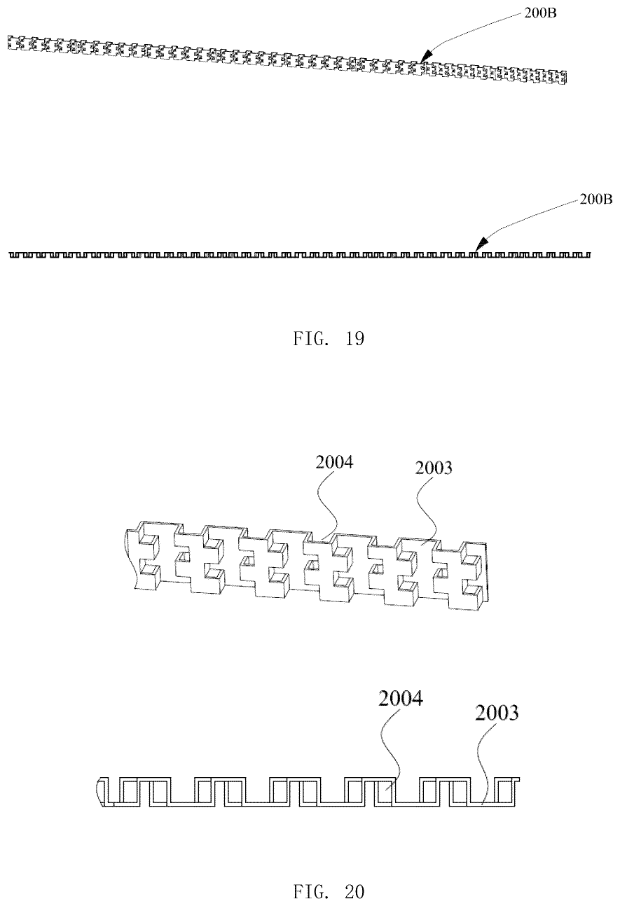

Referring to FIGS. 17-20. FIG. 17 is a schematic diagram of a plate body of a heat-conducting plate in accordance with another embodiment of the present disclosure. FIG. 18 is a partially enlarged view of the plate body shown in FIG. 17. FIG. 19 illustrates alternative views of staggered fin units shown in FIG. 17. FIG. 20 illustrates alternative partial enlarged views of the staggered fin units shown in FIG. 17. The plate body 10B of the heat-conducting plate in the embodiment is similar to the plate body 10, so the similarities will not be repeated here. In this embodiment, the plate body 10B is integrated into the heat-conducting plate. The primary distinction between the heat-conducting plate 1 and this embodiment lies in the unique structure of the plate body 10B, while the remaining structural elements are consistent. According to this embodiment, the heat dissipation device includes the heat-conducting plate, which features the plate body 10B. The key difference in this configuration, compared to the heat dissipation structure 2, is the specific design of the plate body 10B, with all other components and characteristics remaining identical.

As an example illustrated in FIGS. 17-18, the vapor chamber 100B includes a plurality of staggered fin units 200B. The staggered fin units 200B are brazed within the vapor chamber and are sequentially aligned along its longitudinal axis. In one embodiment, the staggered fin unit 200B includes a heat exchange plate 2003 that is connected to the bottom of the vapor chamber 100B. The heat exchange plate 2003 is formed with a plurality of heat exchange recesses 2004. The heat exchange recesses 2004 are evenly spaced and aligned longitudinally, while arranged in a staggered configuration transversely.

In one embodiment, the heat exchange recesses 2004 are square-shaped grooves. These heat exchange recesses 2004 are formed by inward indentations of the heat exchange plate 2003 in a direction away from the vapor chamber 100B. However, the embodiment is not limited thereto. In other embodiments, the heat exchange recesses 2004 can adopt other shapes, such as circular, triangular, trapezoidal, or arcuate profiles.

During operation, the plate body 10b is in contact with the heat-generating region of an electronic device to dissipate heat. The staggered fin units 200B are deliberately positioned to align with the high-power areas of the device that produce the most heat. The plate body 10B absorbs heat from the high-power areas and swiftly transfers it to the staggered fins units 200B. Subsequently, the staggered fin units 200B transfer the absorbed heat to the working fluid within the vapor chamber 100B, enhancing the local heat exchange efficiency of the plate body 10B.

Therefore, embodiments disclosed herein are well adapted to attain the ends and advantages mentioned as well as those that are inherent therein. The particular embodiments disclosed above are illustrative only, as the embodiments disclosed may be modified and practiced in different but equivalent manners apparent to those of ordinary skill in the relevant art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure. Of course, the disclosed embodiments are merely exemplary embodiments and that various modifications can be made without departing from the spirit and scope of the disclosure. Further, it should be understood that various aspects of the embodiment are not mutually exclusive of each other and can be combined as desired by a person of ordinary skill in the art as a matter of design choices.

The embodiments illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some number. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the elements that it introduces.

What is claimed is:

1. A heat-conducting plate, comprising:
a plate body; and
a cover that is mounted to the plate body, wherein
the plate body and the cover together define a vapor chamber,
the plate body includes at least one partition rib that partitions the vapor chamber into at least two first partition chambers,
a first end of the partition rib is connected to a sidewall of the vapor chamber, and a second end of the partition rib extends into the vapor chamber and is spaced apart from an opposite sidewall of the vapor chamber by a gap,
a second partition chamber is formed between the second end of the partition rib and the opposite sidewall and is in fluid communication with the at least two first partition chambers, and
the partition rib tapers from the first end towards the second end.

2. The heat-conducting plate of claim 1, wherein the plate body includes multiple partition ribs that are arranged in parallel and spaced at equal intervals.

3. The heat-conducting plate of claim 1, wherein the partition rib protrudes from a bottom surface of the vapor chamber towards the cover.

4. The heat-conducting plate of claim 3, wherein a plurality of thermal conduction support pillars are disposed within the vapor chamber, a first end of the conduction support pillar is connected to the bottom surface of the vapor chamber, and a second end of the conduction support pillar contacts the cover.

5. The heat-conducting plate of claim 4, wherein at least one conduction support pillar is integrally formed with a corresponding partition rib.

6. The heat-conducting plate of claim 5, wherein the conduction support pillar is designed as a cylindrical post.

7. The heat-conducting plate of claim 1, wherein the first end of each first partition chamber includes a fin locking groove.

8. The heat-conducting plate of claim 1, wherein the cover includes at least two through-slots, and each of the first partition chambers is in fluid communication with a corresponding through-slot.

9. A heat dissipation device, comprising:
a heat-conducting plate, including:
a plate body; and
a cover having at least two through-slots, the cover being mounted to the plate body, wherein
the plate body and the cover together define a vapor chamber,
the plate body includes at least one partition rib that partitions the vapor chamber into at least two first partition chambers, each of the first partition chambers being in fluid communication with a corresponding through-slot,
a first end of the partition rib is connected to a sidewall of the vapor chamber, and a second end of the partition rib extends into the vapor chamber and is spaced apart from an opposite sidewall of the vapor chamber by a gap,
a second partition chamber is formed between the second end of the partition rib and the opposite sidewall and is in fluid communication with the at least two first partition chambers, and
the partition rib tapers from the first end towards the second end;
a plurality of heat dissipation fins, each of the heat dissipation fins extending into a corresponding first partition chamber through a respective through-slot;
at least one securing strip configured to secure the heat dissipation fins; and
a fin protection member configured to protect the heat dissipation fins.

10. The heat dissipation device of claim 9, wherein each of the heat dissipation fins includes at least one insertion rib, each insertion rib extending into a corresponding first partition chamber through a respective through-slot.

11. The heat dissipation device of claim 10, wherein each insertion rib has at least one communication opening, and the communication opening extends into a corresponding first partition chamber when the heat dissipation fin is inserted into the heat-conducting plate.

12. The heat dissipation device of claim 11, wherein each insertion rib includes a communication section that protrudes vertically from the insertion rib, the communication opening is formed in the communication section, each through-slot is recessed outward from both lateral sides along a horizontal direction to form a clearance groove, and the clearance groove is shaped and positioned to accommodate a corresponding communication section.

13. The heat dissipation device of claim 9, wherein the plate body includes multiple partition ribs that are arranged in parallel and spaced at equal intervals.

14. The heat dissipation device of claim 9, wherein the partition rib protrudes from a bottom surface of the vapor chamber towards the cover.

15. The heat dissipation device of claim 9, wherein a plurality of thermal conduction support pillars are disposed within the vapor chamber, a first end of the conduction support pillar is connected to the bottom surface of the vapor chamber, and a second end of the conduction support pillar contacts the cover.

16. The heat-conducting plate of claim 9, wherein at least one conduction support pillar is integrally formed with a corresponding partition rib.

17. The heat dissipation device of claim 16, wherein the conduction support pillar is designed as a cylindrical post.

18. The heat dissipation device of claim 9, wherein the first end of each first partition chamber includes a fin locking groove.

19. The heat dissipation device of claim 9, wherein the securing trip includes at least two first locking slots, the heat dissipation fin includes at least two second locking slots, and the first locking slots are aligned in a one-to-one correspondence with the second locking slots.

20. The heat dissipation device of claim 9, wherein the protection member has a mesh structure and is attached to the heat dissipation fins on a side of that faces away from the heat-conducting plate.
